(19) United States
(12) Patent Application Publication
(10) Pub. No.: US 2004/0238862 A1
(43) Pub. Date: Dec. 2, 2004

(54) Ferroelectrics device and method of manufacturing the same

(76) Inventor: Takashi Ichimori, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/743,073

(22) Filed: Dec. 23, 2003

(30) Foreign Application Priority Data
May 30, 2003 (JP) 2003-153744

(51) Int. Cl. H01L 21/8234; H01L 29/76

(52) U.S. Cl. 257/295; 438/3; 257/296; 438/238; 257/306; 438/244

(57) ABSTRACT

According to the ferroelectric device of the present invention, the crystalline structure in the ferroelectric film is improved and the physical characteristics of the ferroelectric device can improve.

A method for manufacturing a ferroelectric device according to the present invention comprises a step for: forming successively a contact film, a lower electrode, a ferroelectric film and an upper electrode on an insulating film; performing an etching to the upper electrode and the ferroelectric film; and heat-treatment the ferroelectric film under a condition of covering the contact film with the lower electrode.

### BACKGROUND OF THE INVENTION

1. Field of the Invention

The present invention relates to a method of manufacturing a ferroelectric device, and further a ferroelectric device and a FRAM.

2. Description of the Related Art

A ferroelectric capacitor has a structure including a ferroelectric layer sandwiched by a lower electrode layer and an upper electrode layer, as a ferroelectric device. For example, the ferroelectric film consists of PZT or SBT, and the electrode layers consist of Pt. The ferroelectric capacitor can store data in a nonvolatile manner by spontaneous polarization of the ferroelectric film. Such ferroelectric capacitor can be used in a nonvolatile semiconductor memory (FRAM). The stack type FRAM is formed on an insulating film covering a transistor and is electrically connected to a source/drain area by a contact plug formed in the insulating film. The FRAM are vertically disposed above the source/drain area in the transistor and connected each other by the contact plug so that a chip area of the FRAM can be reduced. In typical methods of manufacturing the stack type FRAM, contact holes are opened in the insulating film to expose the source/drain area of the transistor, and contact plug material is inserted into the contact holes of the insulating film. A contact film consisting of a binding film and an oxidation barrier film, a lower electrode, a ferroelectric film and an upper electrode are successively deposited thereon. The deposited body is cut by each cell by using an etching method and the stack type FRAM can be obtained. In such a manufacturing method, a heat treatment is often performed even after the ferroelectric crystal is once created for the purpose of recovering a disordered crystalline structure of the ferroelectric film. For example, an etching step and a diffusion step induce a crystalline structure disorder such as amorphous phase, lattice defects and a compositional shift. The recovery heat treatment should be, therefore, performed to recover the crystalline structure of the ferroelectric film. In such recovery heat treatment, the ferroelectric film is kept for a predetermined period in a temperature for generating a stable crystalline structure so that crystalline disorder is crystallized again.

The conventional method for manufacturing the FRAM is disclosed in page 8 to 9 and FIGS. 11 and 12 of the Japanese Patent Kokai No.2001-44377 (hereinafter referred to as ‘reference 1’). According to this manufacturing method, a diffusion barrier film to prevent mass transfer is deposited on ferroelectric capacitors comprising of a lower electrode, a ferroelectric film and an upper electrode. Further, a heat treatment to reinforce the physical characteristics of this diffusion barrier is performed at 650° C. for 0.5 hours in an oxygen atmosphere.

Another manufacturing method, which utilizes two-step etching method, is disclosed in page 8 and FIGS. 12 to 16 of Japanese Patent Kokai No.2001-36026 (hereinafter referred to as ‘reference 2’).

According to the reference 2, it is disclosed that a two-step etching method is performed after forming a binding film, a lower Pt electrode film, a PZT film (a ferroelectric film) and an upper Pt electrode film. The first etching step is performed so that the upper Pt electrode film, the PZT film, and p part-of the lower Pt electrode are removed and the lower Pt electrode film has a predetermined thickness. Further, a hydrogen barrier film is formed to cover the upper Pt electrode film, the PZT film and the lower Pt electrode film. In the second etching step, the hydrogen barrier film, the lower Pt electrode film and the binding film are etched.

According to the manufacturing method disclosed in the reference 1, the heat treatment is performed with the ferroelectric film covered with a diffusion barrier film. In this structure, an adequate amount of oxygen is not supplied to the ferroelectric film, which is an oxide, and the crystalline structure in the ferroelectric film may be deteriorated. According to the method disclosed in the reference 2, the crystalline structure in the ferroelectric film may be deteriorated, since recovery annealing is not performed after etching the PZT film. Such deterioration of the crystalline structure in the ferroelectric film deteriorates the physical characteristics of the ferroelectric capacitor, too.

In the ferroelectric capacitors according to the references 1 and 2, the capacitor cell area is necessarily enlarged ferroelectric capacitor, since a diffusion barrier film and a hydrogen barrier film as a cover film are formed across surfaces in plural layers.

### OBJECT AND SUMMARY OF THE INVENTION

The primary purpose of the present invention is to improve the characteristics of a ferroelectric device by improving the crystalline structure in a ferroelectric film.

The secondary purpose of the present invention can reduce the ferroelectric capacitor size reducing the cell area in the ferroelectric device.

The method for manufacturing a ferroelectric device according to the present invention comprises the following steps of forming successively a contact film, a lower electrode, a ferroelectric film and an upper electrode on an insulating film; performing an etching to the upper electrode and the ferroelectric film; heat treatment of the ferroelectric film with the contact film covered with the lower electrode. Wherein, the contact film has at least a property of binding film, and preferably has a property of oxidation barrier.

A ferroelectric device according to the present invention comprises a contact film, a lower electrode, a ferroelectric film, an upper electrode and a first cover film. The contact film is formed on an insulating film. The lower electrode is formed across the contact film. The lower electrode has a first portion on the contact film and a second portion on the first portion having a smaller area than that of the first portion. Thus, the first portion of the lower electrode has approximately the same area as the contact film. The ferroelectric film is formed on the second portion of the lower electrode. Thus, the ferroelectric film has a smaller area than that of the contact film. The upper electrode is formed on the ferroelectric film. Thus, the upper electrode has approximately the same area as the ferroelectric film. The first cover film covers side surfaces of the upper electrode, the ferroelectric film and the second portion of the lower electrode. The side surfaces of the first cover film is substantially aligned to the side surfaces of the contact film.

The contact film has at least a property of binding film, and preferably has a property of oxidation barrier.

According to the method for manufacturing a ferroelectric device in the present invention, the contact film is not directly exposed to a high temperature oxidation atmosphere, since the contact film, such as the binding film and the oxidation barrier film, is covered with the lower electrode during the heat treatment. The heat treatment can be, therefore, performed at a sufficiently high temperature and during a sufficient time while preventing deterioration of the contact film. Further, the heat treatment can be performed so as to supply an adequate amount of oxygen to the ferroelectric film, since the side surface of the ferroelectric film is exposed to the atmosphere. While the deterioration of the contact film is prevented and the crystalline structure in the ferroelectric film is improved, the physical characteristics of the ferroelectric device can improve.

According to the ferroelectric device in the present invention, the ferroelectric film and the upper electrode have a smaller area than that of the contact film and the first portion of the lower electrode, and a first cover film is formed so as to fill in flat the step formed between side surfaces of the ferroelectric film and the upper electrode and that of the contact film and the first portion of the lower electrode. Such ferroelectric device can be made small.

### BRIEF EXPLANATION OF THE DRAWINGS

FIGS. 1 to 6 are sectional views for explaining a manufacturing process of the FRAM including a ferroelectric capacitor according to the first embodiment;

FIGS. 7 to 12 are sectional views for explaining a manufacturing process of the FRAM including a ferroelectric capacitor according to the second embodiment;

FIGS. 13 to 18 are sectional views for explaining a manufacturing process of the FRAM including a ferroelectric capacitor according to the third embodiment.

### DETAILED DESCRIPTION OF THE EMBODIMENT

### (1) First Embodiment

(Manufacturing Process)

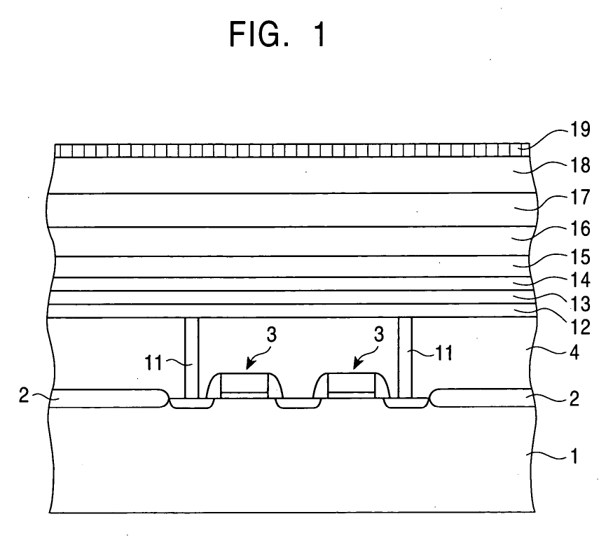

FIGS. 1 to 6 are drawings to explain the manufacturing process of the FRAM including a ferroelectric capacitor according to the first embodiment.

As shown in FIG. 1, transistors 3 are formed to be separated from a semiconductor substrate 1 by an element isolation region 2 formed by LOCOS process, etc., and these surfaces are covered with an interlayer insulating film 4 such as silicon oxide film, then the top of the insulating film is plnarized. The interlayer insulating film 4 is opened to expose a source/drain region of the transistor 3 and the hole of the interlayer insulating film 4 is filled with contact plug material consisting of tungsten (W) or poly-silicon (p-Si). A binding film 12 consisting of TiN, a binding film 13 consisting of IrHf, an oxidation barrier film 14 consisting of Ir, an oxidation barrier film 15 consisting of IrO and a lower electrode 16 consisting of Pt are successively deposited on the interlayer insulating film 4, for example, by a sputtering method. While the oxidation barrier films 14, 15 prevent oxygen gas from reaching to the contact plug 11 through the lower electrode 16, these films prevent Pb from diffusing from a ferroelectric film 17 to the interlayer insulating film 4. The binding films 12, 13 have a function for increasing adhesion with the interlayer insulating film 4. Materials of the oxidation barrier films 14, 15 and the binding films 12, 13 are selected from thermally stable materials, which have low reactivity to the contacted materials at each heat treatment temperature in the semiconductor process and have high conductivity so that the contact resistance does not become high. Oxidation barrier films 14, 15 are selected from materials which can prevent passing not only oxygen, but also hydrogen. These materials may be selected from AlN, SrRuO3, ZrOx, RuOx and SrOx. The binding films 12, 13 and the oxidation barrier films 14, 15 comprise a contact film inserted between the lower electrode 16 and the contact plug 11.

A ferroelectric film 17 consisting of SBT (SrBi2TaO9) is deposited on the lower electrode 16 by spin-coating method or a CVD method. This body is subjected to a high temperature oxidizing atmosphere at 700 to 750° C. for 0.5 to 1 hr to crystallize the ferroelectric film 17 (crystallizing heat treatment). The crystallizing heat treatment may be performed under the condition of a high temperature oxidizing atmosphere at 800° C. for 0.5 to 1 min using RTA (Rapid Thermal Anneal). A ferroelectric film 17 may consist of PZT (Pb(Zr,Ti)O3), SBTN (SrBi2(Ta,Nb)2O9) or BLT ((Bi,La)4Ti3O12). An upper electrode 18 consisting of Pt is deposited on the ferroelectric film 17, for example, by sputtering method after the crystallizing heat-treatment, and further a hard mask 19 consisting of SiO2 and/or TiN is deposited thereon by plasma CVD or sputtering, for example.

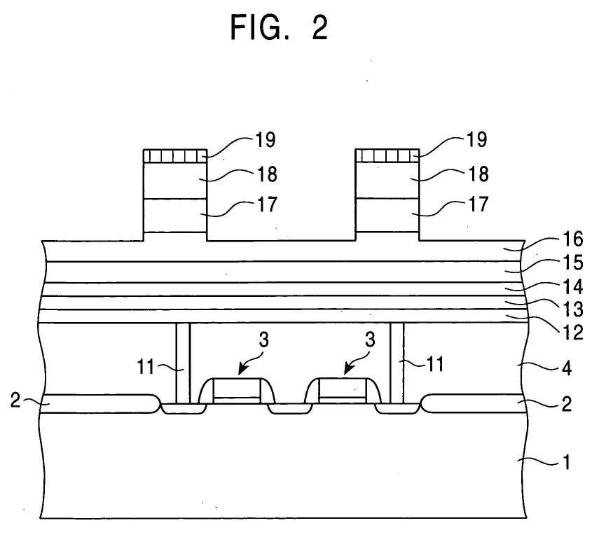

A resist pattern is formed on the hard mask 19. As shown in FIG. 2, the resist is removed after a pattern processing is performed to the hard mask 19. A first etching process is performed with the hard mask 19. In the first etching process, the hard mask 19 is used as an etching mask, and the upper electrode 18, the ferroelectric film 17 and a part of the lower electrode 16 are etched. The lower electrode 16 is etched from its surface to a predetermined thickness and so that a part of the lower electrode is left on the contact film (the oxidation barrier films 14, 15 and the binding films 12, 13).

The ferroelectric film 17 is kept at a temperature where the preferred crystal structure is generated stably, so that the region with disordered crystal is recrystalized. The recovery heat-treatment can recrystalize disorder in the crystal structure, such as amorphous phase, lattice defects and a compositional shift, which may be induced in the ferroelectric film 17 by the first etching step and the diffusion step. The recovery heat-treatment is typically performed in a high temperature oxidizing atmosphere at 700 to 750° C. for 0.5 to 1 hr, or by employing rapid thermal oxidization at 800° C. for 0.5 to 1 min.

The recovery heat-treatment is performed under the condition of covering the oxidation barrier films 14 and 15 and the binding films 12 and 13 with the lower electrode 16, and the oxidation barrier films 14 and 15 and the binding films 12 and 13 are not directly subjected to such high temperature oxidizing atmosphere. Therefore, a film peeling and a deterioration of the film characteristics based upon the oxidization of the oxidation barrier films 14 and 15 and the binding films 12 and 13 are prevented. Further, sublimation of Ir in the oxidation barrier films 14 and 15 and the binding film 13 does not occur and so it hardly causes insulation failure based upon Ir deposition on the side surface of the ferroelectric film 17. Since binding layers 12 and 13 are not exposed to oxidation atmosphere, oxygen diffusion to the contact plug 11 along the binding films 12 and 13 is avoided, hence oxidation of the contact plugs is suppressed.

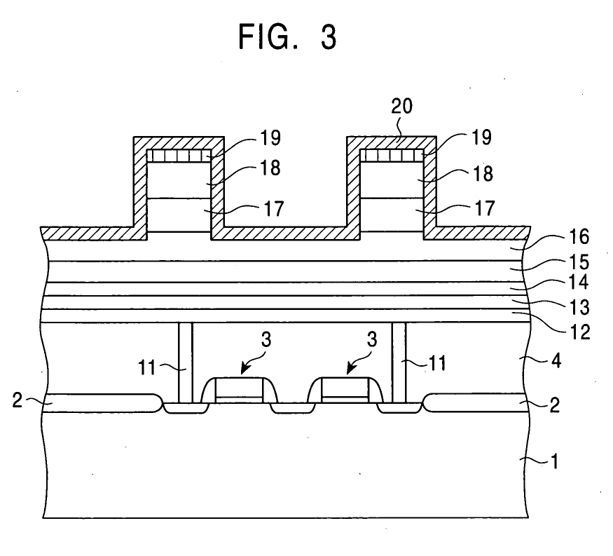

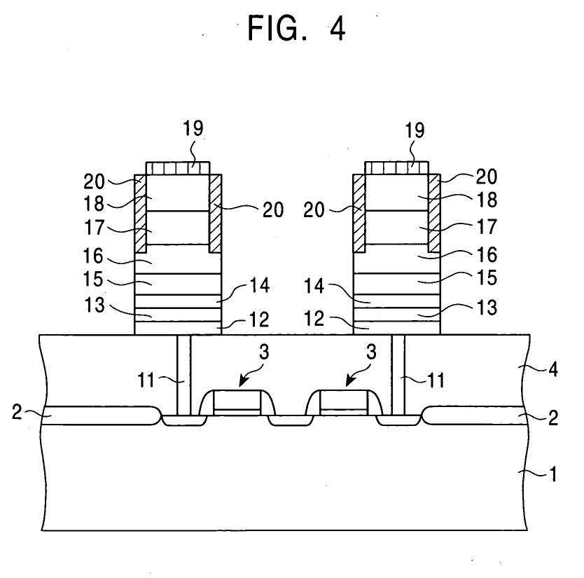

As shown in FIG. 3, a first cover film 20 consisting of Alumina (Al2O3) is deposited as a hydrogen infiltration preventive film. As shown in FIG. 4, the first cover film 20, the remaining lower electrode 16, the oxidation barrier films 14, 15 and the binding films 12, 13 are etched by using a Cl2+Ar etching gas, in a self-alignment manner, as the second etching step. A hard mask 19 functions as an etching stopper to prevent the upper electrode 18 from being etched. In case of the hard mask 19 consisting of TiN, a sufficient thickness is required to the hard mask 19, since the above etching gas may etch the hard mask 19. According to the etching process in a self-alignment manner with the hard mask 19 and the first cover film 20, the side surface of the first cover film 20 is substantially aligned to the side surfaces of the lower electrode 16, the oxidation barrier films 14, 15 and the binding films 12, 13. More specifically, the lower electrode 16 is comprised of the second portion etched in the first etching step and the first portion unetched in the first etching step. The first cover film 20 is formed on the side surfaces of the second portion and the top surface of the first portion. Thus, the first cover film 20 prevents from enlarging an area of the ferroelectric capacitor.

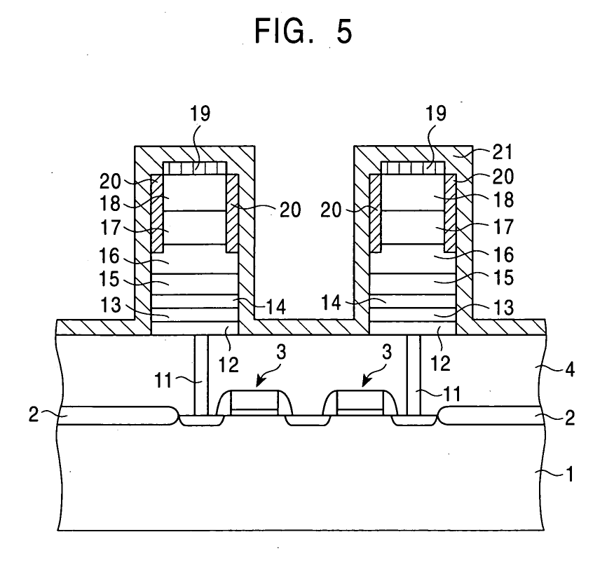

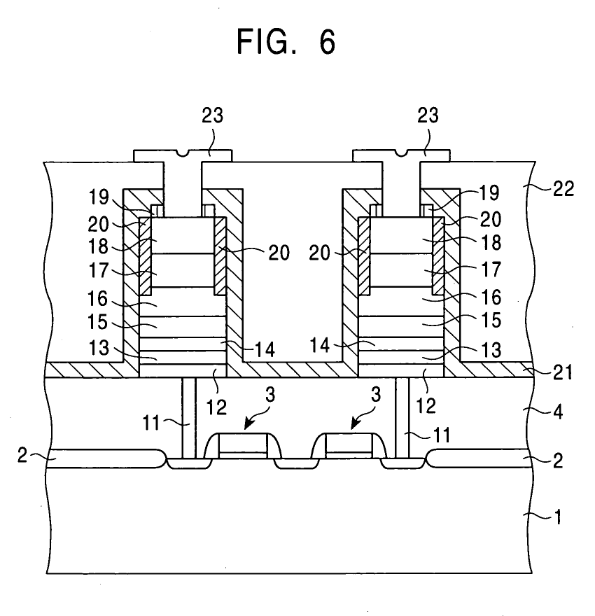

As shown in FIG. 5, a second cover film 21 consisting of Alumina (Al2O3) as a hydrogen infiltration preventive film is deposited. In this embodiment, the second cover film 21 is formed on the upper electrode 18 without removing the hard mask 19. However, the second cover film 21 may be formed after the hard mask 19 is removed after the second etching step. After this, an interlayer insulating film 22 is deposited as shown in FIG. 6 and a contact hole is opened to form a wiring 23 connecting to the upper electrode 18.

According to the manufacturing method for the ferroelectric capacitor in this embodiment, the recovery heat-treatment of the ferroelectric film 17 is performed under the condition of covering the oxidation barrier films 14 and 15 and the binding films 12 and 13 with the lower electrode 16. Thus, the recovery heat-treatment can be performed during a sufficient time while the oxidation barrier films 14, 15 and the binding films 12, 13 are not directly exposed to a high temperature oxidation atmosphere. According to such recovery heat-treatment, it is prevented to produce a film peeling and a deterioration of the film characteristics by the oxidization of the oxidation barrier films 14, 15 and the binding films 12, 13. Further, sublimation of Ir as a conductive material in the oxidation barrier films 14 and 15 and the binding film 13 does not occur and so it hardly causes insulation failure based upon Ir deposition on the side surfaces of the ferroelectric film 17. The binding films 12 and 13 are not directly subjected to the oxidizing atmosphere, and so an oxygen gas can not reach to the contact plug 11 along the binding films 12 and 13. Thus, the oxidation of the contact plug 11 may be prevented. Further, in the recovery heat-treatment, exposing the end surfaces of the ferroelectric film 17 can supply a sufficient amount of oxygen to the ferroelectric film 17. As a result, the crystalline structure in the ferroelectric film 17 and the characteristics of the ferroelectric capacitor can improve while the deteriorations of the oxidation barrier films 14, 15, the binding films 12, 13 and the contact hole 11 are prevented.

In case of the recovery heat-treatment using a nitrogen gas, a reduction of the oxidation barrier films 14, 15 and the binding films 12, 13 is prevented.

In the second etching process the lower electrode 16, the oxidation barrier films 14, 15 and the binding films 12, 13 are etched in a self-alignment manner using the first cover film 20 and the hard mask 19. So, the side surfaces of the first cover film 20 are formed so as to be substantially aligned to the side surfaces of the lower electrode 16, the oxidation barrier films 14, 15 and the binding films 12, 13. Thus, the first cover film 20 prevents from enlarging an area of the ferroelectric capacitor and the ferroelectric capacitor size can be reduced.

### (2) Second Embodiment

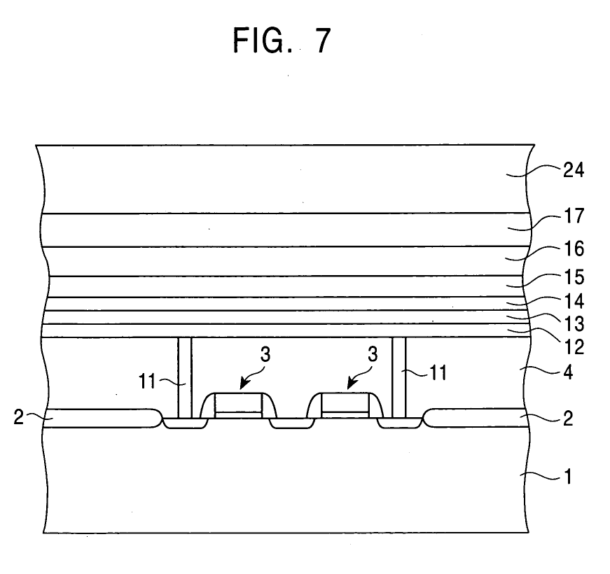

FIGS. 7 to 12 are drawings to explain a manufacturing process of the FRAM including a ferroelectric capacitor according to the second embodiment. In the first embodiment the hard mask 19 is formed on the upper electrode 18 as the etching stopper in the second etching step. However, in this embodiment, an upper electrode 24 is not provided a hard mask 19 and is formed thicker by a film thickness corresponding to the thickness which will be etched.

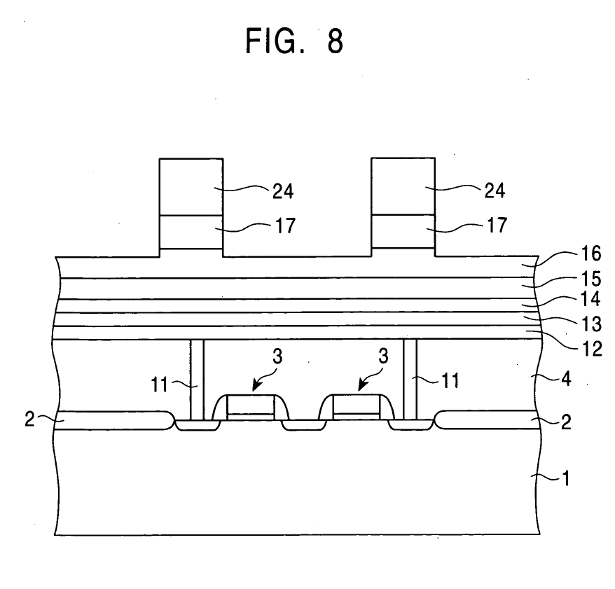

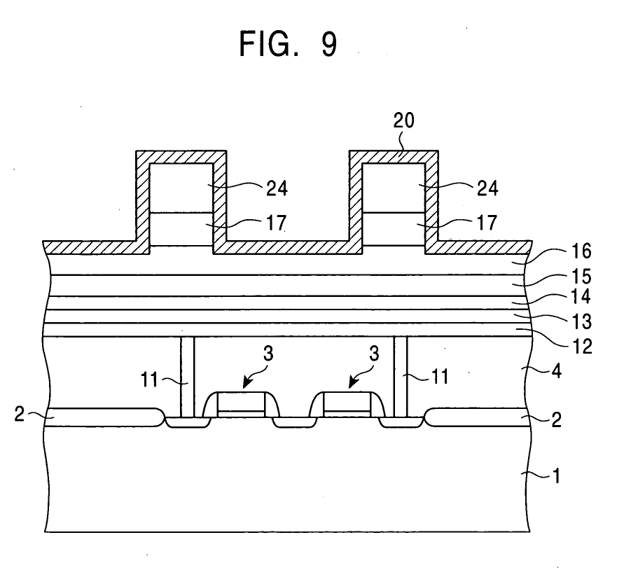

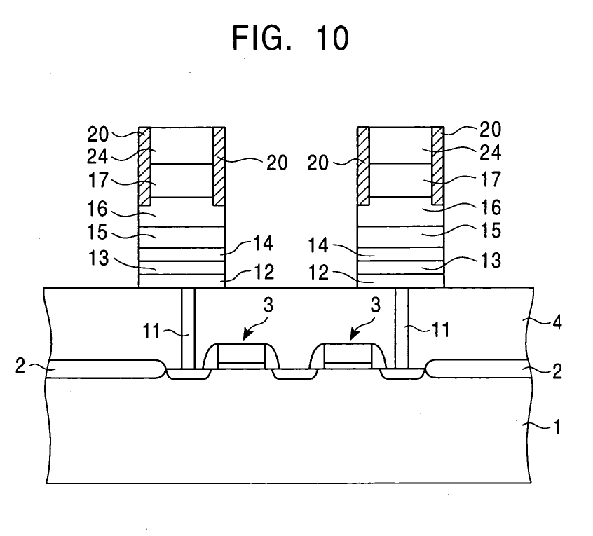

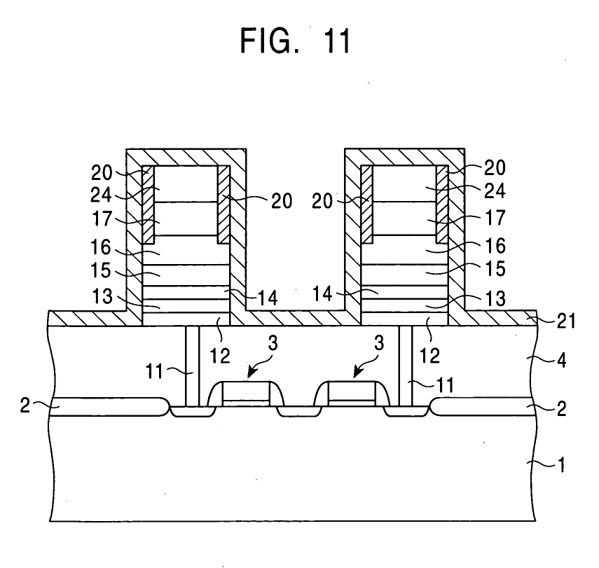

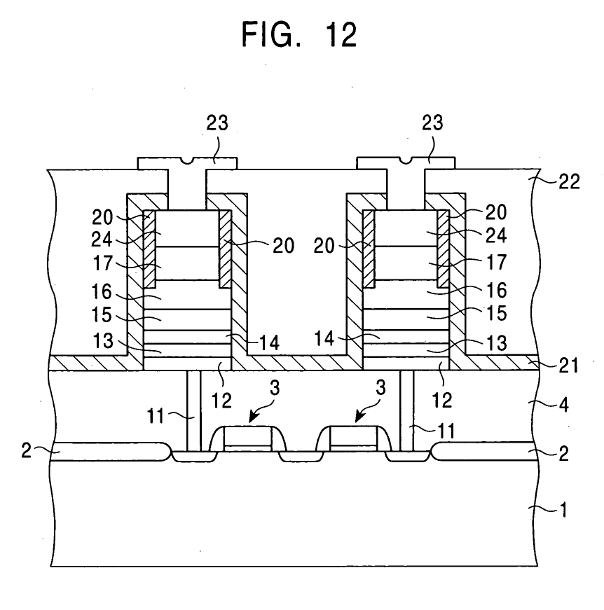

As shown in FIG. 7, an upper electrode 24 is formed similarly to the first embodiment after binding films 12, 13, oxidation barrier films 14, 15, a lower electrode 16 and a ferroelectric film 17 are formed on an interlayer insulating film 4. In this embodiment, the upper electrode 24 is formed thicker by a film thickness corresponding to the thickness which will be etched so that a predetermined thickness can be obtained after etching the surface of the upper electrode 24. A resist pattern is formed on the upper electrode 24. As shown in FIG. 8, the upper electrode 24 and the ferroelectric film 17 are etched and further the lower electrode 16 is etched to a predetermined thickness from its surface. (first etching step) The recovery heat-treatment is performed to recover the crystalline structure in the ferroelectric film 17 after a resist on the upper electrode 24 is removed. As shown in FIG. 9, the first cover film is deposited. As shown in FIG. 10, the first cover film 20, the lower electrode 16, the oxidation barrier films 14, 15 and the binding films 12, 13 are etched in a self-alignment manner. (second etching step) The surface of the upper electrode 24 may be etched after the first cover film 20 on the upper electrode 24 is removed by the etching. The upper electrode 24 is formed thicker by a film thickness corresponding to the thickness which will be etched and so the upper electrode 24 is formed to be a predetermined thickness. As shown in FIG. 11, the second cover film is deposited. As shown in FIG. 12, the interlayer insulating film 22 is deposited and a contact hole is opened to form a wiring 23 to connect to the upper electrode 24.

According to this embodiment, the upper electrode 24 can have a predetermined thickness after the etching step, since the upper electrode 24 is formed thicker by a film thickness corresponding to the thickness which will be etched in the second etching step.

### (3) Third Embodiment

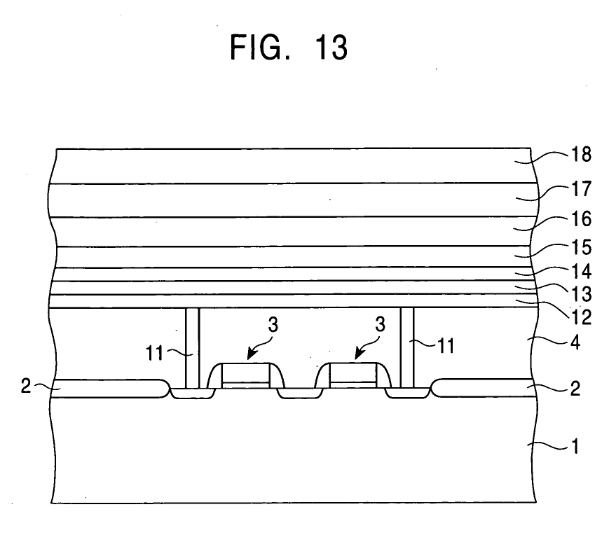

FIGS. 13 to 18 are drawings to explain a manufacturing process of the FRAM including a ferroelectric capacitor according to the third embodiment. In the first embodiment the hard mask 19 is formed on the upper electrode 18 as the etching stopper in the second etching step. However, in this embodiment, an upper electrode 24 is not provided with a hard mask 19, and a resist pattern is used in the second etching step.

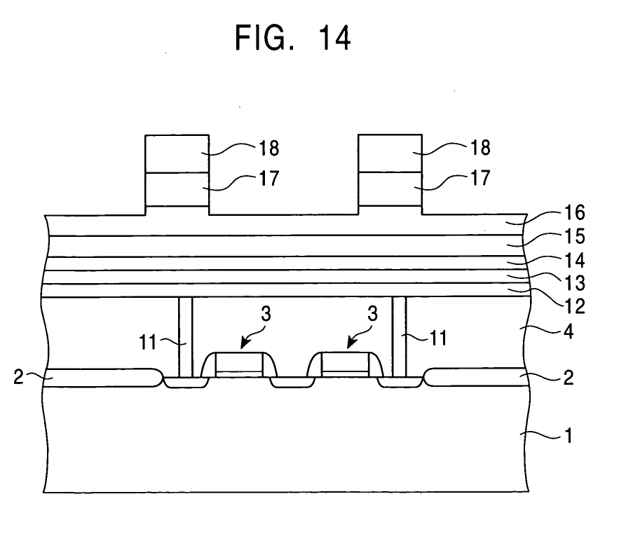

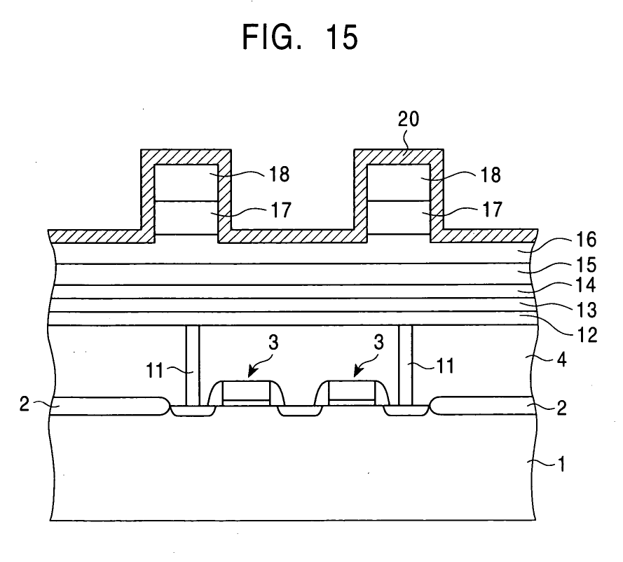

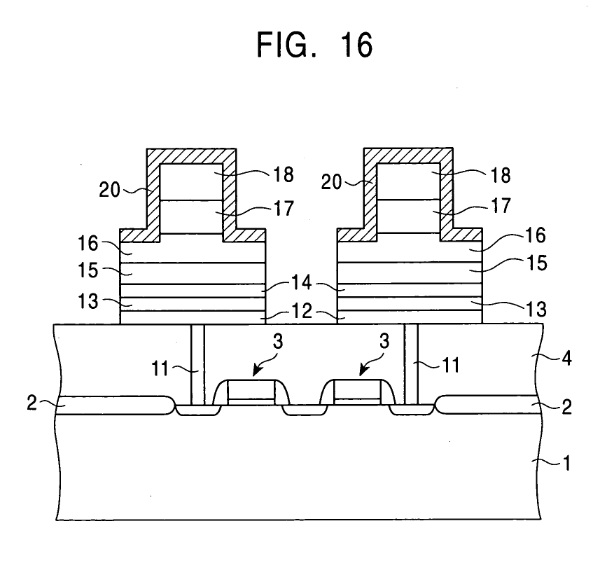

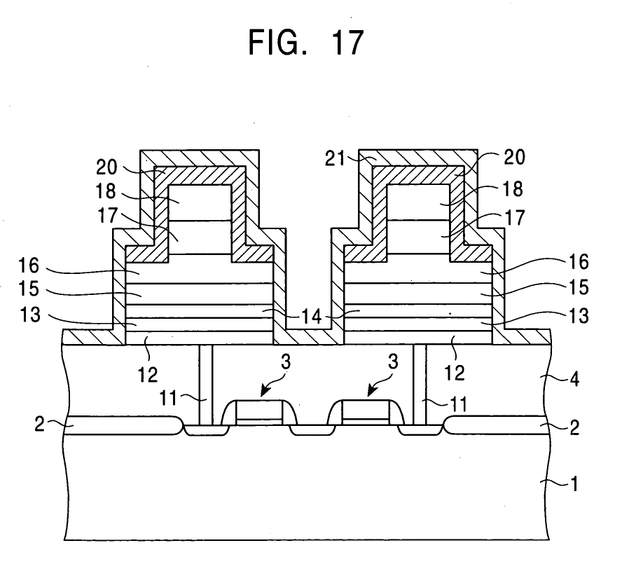

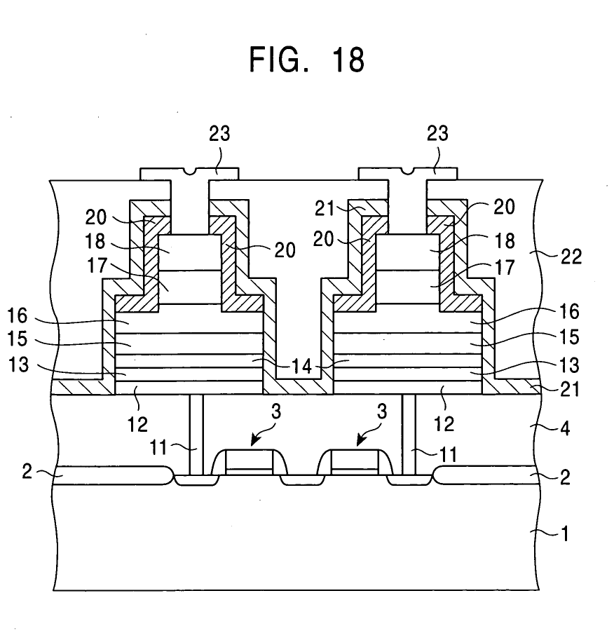

As shown in FIG. 13, binding films 12, 13, oxidation barrier films 14, 15, a lower electrode 16, a ferroelectric film 17 and an upper electrode 18 are formed similarly to the first embodiment on the interlayer insulating film 4. A resist pattern is formed on the upper electrode 18. As shown in FIG. 14, the upper electrode 18 and the ferroelectric film 17 are etched and the lower electrode 16 is etched to a predetermined thickness from its surface. (first etching step) The recovery heat-treatment is performed to recover the crystalline structure in the ferroelectric film 17 after a resist on the upper electrode 24 is removed. As shown in FIG. 15, a resist pattern 20 is formed after the first cover film is deposited. As shown in FIG. 16, the first cover film 20, the lower electrode 16, the oxidation barrier films 14, 15 and the binding films 12, 13 are etched. (second etching step) As shown in FIG. 17 the second cover film 21 is deposited after the resist on the first cover film 20 is removed. As shown in FIG. 18, an interlayer insulating film 22 is deposited and a contact hole is opened to form a wiring 23 connecting to the upper electrode 24. According to this embodiment, the second etching step is performed after the resist pattern is formed on the first cover film 20, and so it is prevented to etch the surface of the upper electrode 18.

### (4) Other Embodiments

(a) According to the above embodiments, disorders in the crystalline structure in the ferroelectric film 17 are mainly induced in the etching step and diffusion step. The recovery heat-treatment is, therefore, performed after the first etching step. However, in such case, forming the first cover film 20 may induce disorders in the crystalline structure to the ferroelectric film 17, so that the recovery heat-treatment of the ferroelectric film 17 may be performed again after the step for forming the second cover film 21. When the binding films 12, 13 and the oxidation barrier films 14, 15 are covered with the second cover film 21, the recovery heat treatment of the crystalline structure of the ferroelectric film 17 can be performed so that such films are not directly subjected to the high temperature oxidizing atmosphere.

(b) According to the above embodiments, the lower electrode 16 are etched to a predetermined thickness from the surface. If the ferroelectric film 17 is wholly removed, etching of the lower electrode 16 is not needed. In such a case, the recovery heat-treatment can be also performed under the condition covering the oxidation barrier films 14 and 15 and the binding films 12 and 13 with the lower electrode 16. Thus, the similar effects in the above embodiments are obtained.

According to the present invention, the heat-treatment of the ferroelectric film is performed under the condition of covering the contact film (the oxidation barrier film and the binding film) with the lower electrode and so the contact film is not directly exposed to a high temperature oxidation atmosphere. Thus, the heat-treatment can be performed during a sufficient time while the deterioration of the contact film is prevented. Further, the side surfaces of the ferroelectric film are exposed by the etching and so the heat-treatment can be performed with supplying a sufficient amount of oxygen to the ferroelectric film. As the result, the crystalline structure in the ferroelectric film and the characteristics of the ferroelectric device can improve with preventing the deterioration of the contact film.

According to the other present invention, the ferroelectric film and the upper electrode are formed to a smaller area than the contact film and the first portion of the lower electrode, and the first cover film is formed to fill in the step. The forming the first cover film can prevent from enlarging an area of the ferroelectric device and provide a small area to the ferroelectric device.

What is claimed is:

1. A method for manufacturing a ferroelectric device, comprising steps of: providing an insulating substrate; forming a multi layer body depositing successively a contact film, a lower electrode, a ferroelectric film and an upper electrode on said insulating substrate; and etching said multi layer body,
wherein said etching step including:
a first etching step for etching said upper electrode and said ferroelectric film;
a heat treatment step for heat-treatment said ferroelectric film under a condition of covering said contact film with said lower electrode; and
a second etching step for etching said lower electrode and said contact film to expose said insulating substrate.

2. The method for manufacturing a ferroelectric device according to claim 1, wherein said insulating film is formed on a semiconductor substrate having a transistor, and a contact plug is formed so as to pass through said insulating film and electrically connects said transistor to said contact film.

3. The method for manufacturing a ferroelectric device according to claim 1, wherein at least a part of said lower electrode is etched in said first etching step.

4. The method for manufacturing a ferroelectric device according to claim 1, wherein said second etching step includes forming a first cover film so as to cover said upper electrode, said ferroelectric film and said lower electrode and etching said first cover film together with said multi layer body.

5. The method for manufacturing a ferroelectric device according to claim 4, wherein said first cover film, said lower electrode and said contact film are etched, in a self-alignment manner, in said second etching step.

6. The method for manufacturing a ferroelectric device according to claim 5, wherein said second etching step includes a step for forming a hard mask on said upper electrode as an etching stopper before performing the etching.

7. The method for manufacturing a ferroelectric device according to claim 4, wherein said second etching step includes forming a resist pattern on said first cover film before performing the etching.

8. The method for manufacturing a ferroelectric device according to claim 1, further comprising a step for forming a second cover film so as to cover said multi layer body after said second etching step.

9. The method for manufacturing a ferroelectric device according to claim 8, further comprising an additional heat treatment step for heat-treatment said ferroelectric film after said second cover film forming step.

10. The method for manufacturing a ferroelectric device according to claim 1, wherein said contact film includes a binding film.

11. The method for manufacturing a ferroelectric device according to claim 10, wherein said contact film further includes an oxidation barrier film.

12. The method for manufacturing a ferroelectric device according to claim 1, wherein said heat-treatment is performed to recover a crystalline structure in the ferroelectric film.

13. The method for manufacturing a ferroelectric device according to claim 9, wherein said additional heat-treatment is performed to recover a crystalline structure of the ferroelectric film.

14. A ferroelectric device comprising:
a contact film formed on an insulating film;
a lower electrode formed across said contact film;
a ferroelectric film formed on said lower electrode so as to have a smaller area than that of said contact film;
an upper electrode formed across said ferroelectric film; and
a first cover film covering side surfaces of at least said upper electrode and said ferroelectric film so as to align side surfaces of said first cover film to side surfaces of said contact film.

15. The ferroelectric devices according to claim 14, wherein said insulating film is formed on a semiconductor substrate having a transistor and a contact plug is formed so as to pass through said insulating film and electrically connects said transistor to said contact film.

16. The ferroelectric devices according to claim 14, wherein said lower electrode has a first portion contacting said contact film and a second portion contacting said ferroelectric film, and said second portion has a smaller area than that of said first portion.

17. The ferroelectric devices according to claim 14, further comprising a second cover film covering said contact film, said lower electrode, said ferroelectric film, said upper electrode and said first cover film except for a part of said upper electrode.

18. The ferroelectric devices according to claim 14, wherein said contact film includes a binding film.

19. The ferroelectric devices according to claim 18, wherein said contact film further includes an oxidation barrier film.

20. A FRAM comprising:
a semiconductor substrate having a transistor;
an insulating film formed on said semiconductor substrate;
a contact plug formed in said insulating film to electrically connect to said transistor;
a contact film formed on said insulating film to electrically connect to said contact plug;
a lower electrode formed across said contact film;
a ferroelectric film formed on said lower electrode so as to have a smaller area than that of said contact film;
an upper electrode formed across said ferroelectric film; and
a first cover film covering side surfaces of at least said upper electrode and said ferroelectric film so as to align side surfaces of said first cover film to side surfaces of said contact film.
